(19) United States
(12) Patent Application Publication
(10) Pub. No.: US 2026/0190906 A1
(43) Pub. Date: Jul. 2, 2026

(54) SUBSTRATE PROCESSING METHOD AND SUBSTRATE PROCESSING APPARATUS

(71) Applicant: SEMES CO., LTD., Cheonan-si (KR)

(72) Inventors: Min Jung KIM, Bucheon-si (KR); Dong Hee SON, Yongin-si (KR); Eun Hee JEONG, Namyangju-si (KR)

(73) Assignee: SEMES CO., LTD., Cheonan-si (KR)

(21) Appl. No.: 19/436,875

(22) Filed: Dec. 30, 2025

(30) Foreign Application Priority Data
Dec. 31, 2024 (KR) 10-2024-0202753

(51) Int. Cl. H10P 72/00; H10P 72/76

(52) U.S. Cl. CPC H10P 72/0414; H10P 72/0408; H10P 72/0602; H10P 72/7618

(57) ABSTRACT

Disclosed is a substrate processing method including: a liquid treatment operation of processing a substrate by supplying a treatment liquid to the substrate supported on a spin head; and a bowl cleaning operation of cleaning a bowl surrounding the spin head and simultaneously stabilizing a temperature of a treatment fluid discharged from a back nozzle of the spin head before the liquid treatment operation.

### CROSS-REFERENCE TO RELATED APPLICATION

This application claims priority to and the benefit of Korean Patent Application No. 10-2024-0202753 filed in the Korean Intellectual Property Office on Dec. 31, 2024, the entire contents of which are incorporated herein by reference.

### TECHNICAL FIELD

The present invention relates to a substrate processing method and a substrate processing apparatus.

### BACKGROUND ART

In general, various processes, such as a photoresist coating process, a developing process, an etching process, and an ashing process, are performed in the process of processing a glass substrate or wafer in the manufacturing of flat panel display devices or semiconductors. In each process, a wet cleaning process using chemical or pure water (deionized water) is performed to remove various contamination materials attached to the substrate.

The substrate cleaning process supplies a chemical to a surface of a substrate placed on a rotating spin head. The chemical is scattered from the substrate by centrifugal force. Most of the scattered chemical is recovered by a bowl (recovery cup) surrounding the spin head, but some of the chemical remains on a wall surface of the bowl or a chucking pin of the spin head.

The chemical remaining in the bowl and the spin head becomes a contamination source that contaminates the substrate. Therefore, a bowl cleaning process for cleaning contaminated bowls is periodically required.

On the other hand, since a substrate cleaning facility does not have a pre-dispense function of a back nozzle, there are problems such as the generation of full-surface particles due to the stagnation of the chemical and the etching (E/R) drop of the first substrate due to temperature loss when using a high-temperature chemical (e.g., SC1).

### SUMMARY OF THE INVENTION

The present invention has been made in an effort to provide a substrate processing apparatus and a substrate processing method capable of stabilizing a temperature of a chemical of a back nozzle during bowl cleaning.

The present invention has also been made in an effort to provide a substrate processing apparatus and a substrate processing method capable of improving bowl cleaning efficiency.

The objectives of the present disclosure are not limited thereto and other objectives not stated herein may be clearly understood by those skilled in the art from the following description.

An exemplary embodiment of the present disclosure, a substrate processing method may comprise: a liquid treatment operation of processing a substrate by supplying a treatment liquid to the substrate supported on a spin head; and a bowl cleaning operation of cleaning a bowl surrounding the spin head and simultaneously stabilizing a temperature of a treatment fluid discharged from a back nozzle of the spin head before the liquid treatment operation.

According to the exemplary embodiment of the present invention, wherein the bowl cleaning operation may include: a loading operation of loading a dummy substrate onto the spin head; and a cleaning operation in which an upper nozzle member discharges a cleaning fluid to an upper surface of the dummy substrate rotated by the spin head and the back nozzle discharges the cleaning fluid to a bottom surface of the dummy substrate.

According to the exemplary embodiment of the present invention, wherein the cleaning operation may include: a pre-dispense operation in which the back nozzle discharges a chemical to the bottom surface of the dummy substrate; and a rinse treatment operation in which the back nozzle discharges a rinse liquid to the bottom surface of the dummy substrate.

According to the exemplary embodiment of the present invention, wherein the cleaning operation further may include a dry treatment operation in which the back nozzle discharges dry gas to the bottom surface of the dummy substrate after the rinse treatment operation.

According to the exemplary embodiment of the present invention, wherein in the pre-dispense operation, a discharge amount and discharge time may be set differently according to the type of chemical and a set temperature of the chemical.

According to the exemplary embodiment of the present invention, wherein the pre-dispense operation is performed for a period of time during which the temperature of the chemical discharged from the back nozzle may be stabilized.

According to the exemplary embodiment of the present invention, wherein in the pre-dispense operation, a discharge amount and discharge time of the chemical may increase as a set temperature of the chemical discharged from the back nozzle increases.

According to the exemplary embodiment of the present invention, wherein in the liquid treatment operation, the chemical of which the temperature is stabilized in the bow cleaning operation may be supplied to the bottom surface of the substrate.

According to the exemplary embodiment of the present invention, wherein in the pre-dispense operation and the rinse treatment operation, the dummy substrate is rotated at a first rotation speed, and in the dry treatment operation, the dummy substrate may be rotated at a second rotation speed.

According to the exemplary embodiment of the present invention,, wherein the second rotation speed may be higher than the first rotation speed.

According to the exemplary embodiment of the present invention, wherein in the cleaning operation, the rinse liquid is discharged to the upper surface of the dummy substrate, and a chemical, a rinse liquid, and dry gas are sequentially discharged to the bottom surface of the dummy substrate, and the rinse liquid discharged to the upper surface of the dummy substrate may be stopped before the dry gas is discharged to the bottom surface of the dummy substrate.

An exemplary embodiment of the present disclosure, a substrate processing apparatus may comprise: a spin head for supporting a substrate and rotating the substrate; a bowl provided to surround the spin head; an upper nozzle member for injecting a rinse liquid onto an upper surface of the substrate placed on the spin head; a back nozzle unit provided to the spin head and injecting a treatment fluid to a bottom surface of the substrate placed on the spin head; and a controller for controlling the back nozzle unit so that pre-discharge of the back nozzle unit is performed toward the bottom surface of the dummy substrate in a state where the dummy substrate is seated on the spin head during the bowl cleaning.

According to the exemplary embodiment of the present invention, wherein the back nozzle unit may include a first nozzle for discharging a chemical, a second nozzle for discharging a rinse liquid, and a third nozzle for discharging dry gas.

According to the exemplary embodiment of the present invention, wherein the controller may controls the first nozzle, the second nozzle, and the third nozzle so that the back nozzle unit sequentially discharges the chemical, rinse liquid, and dry gas during the bowl cleaning.

According to the exemplary embodiment of the present invention, wherein the controller may controls the upper nozzle member so that the rinse liquid is discharged to the upper surface of the dummy substrate during the bowl cleaning.

According to the exemplary embodiment of the present invention, wherein the controller may controls the first nozzle so that the chemical is discharged for a period of time during which a temperature of the chemical discharged from the first nozzle is stabilized during the bowl cleaning.

According to the exemplary embodiment of the present invention, wherein the controller may sets a discharge amount and discharge time of the chemical discharged from the first nozzle during the bowl cleaning differently according to a type of chemical discharged from the first nozzle and a set temperature of the chemical.

According to the exemplary embodiment of the present invention, wherein the discharge amount and the discharge time of the chemical may increase as the set temperature of the chemical discharged from the first nozzle increases.

An exemplary embodiment of the present disclosure, a substrate processing method in a substrate processing apparatus including a spin head that rotatably supports a substrate and has a back nozzle for discharging a chemical to a bottom surface of the substrate, an upper nozzle member that discharges a rinse liquid to an upper surface of the substrate, and a bowl disposed in a circumference of the spin head, the substrate processing method comprising: a liquid treatment operation in which the upper nozzle member and the back nozzle discharge a chemical to an upper surface and a lower surface of the substrate supported by the spin head to process the substrate; and a bowl cleaning operation of cleaning a bowl surrounding the spin head and simultaneously stabilizing a temperature of the chemical discharged from the back nozzle before the liquid treatment operation, wherein the bowl cleaning operation includes: a loading operation of loading a dummy substrate onto the spin head; and a cleaning operation in which the upper nozzle member discharges a rinse liquid to an upper surface of the dummy substrate rotated by the spin head, and the back nozzle discharges the chemical, rinse liquid, and dry gas to a bottom surface of the dummy substrate, the cleaning operation includes: a pre-dispense operation in which the back nozzle discharges the chemical to the bottom surface of the dummy substrate for a period of time during which a temperature of the chemical discharged from the back nozzle is stabilized; a rinse treatment operation in which the back nozzle discharges the rinse liquid to the bottom surface of the dummy substrate; and a dry treatment operation in which the back nozzle discharges dry gas to the bottom surface of the dummy substrate after the rinse treatment operation, and in the pre-dispense operation, a discharge amount and discharge time are set differently according to the type of chemical and a set temperature of the chemical.

According to the exemplary embodiment of the present invention, wherein the discharge amount and the discharge time of the chemical in the pre-dispense operation increase as a set temperature of the chemical discharged from the back nozzle increases, in the liquid treatment operation, the chemical temperature-stabilized in the bowl cleaning operation is supplied to the bottom surface of the substrate, in the pre-dispense operation and the rinse treatment operation, the dummy substrate is rotated at a first rotation speed, and in the dry treatment operation, the dummy substrate may be rotated at a second rotation speed higher than the first rotation speed.

According to the exemplary embodiment of the present invention, it is possible to remove stagnant particles of the chemical and stabilize the temperature of the chemical during the cleaning of the bowl.

According to the exemplary embodiment of the present invention, it is possible to increase the cleaning range of the bowl.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing facility to which a substrate processing apparatus according to an exemplary embodiment of the present invention is provided.

FIG. 2 is a top plan view of the substrate processing apparatus of FIG. 1.

FIG. 3 is a cross-sectional view of the substrate processing apparatus of FIG. 1.

FIG. 4 is a diagram for describing a back nozzle unit.

FIG. 5 is a flowchart of a substrate processing method according to an exemplary embodiment of the present invention.

FIG. 6 is a table illustrating a supply time point of a chemical, a rinse liquid, and dry gas in a bowl cleaning operation.

FIG. 7 is a diagram illustrating a process of cleaning a bowl by a rinse liquid.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

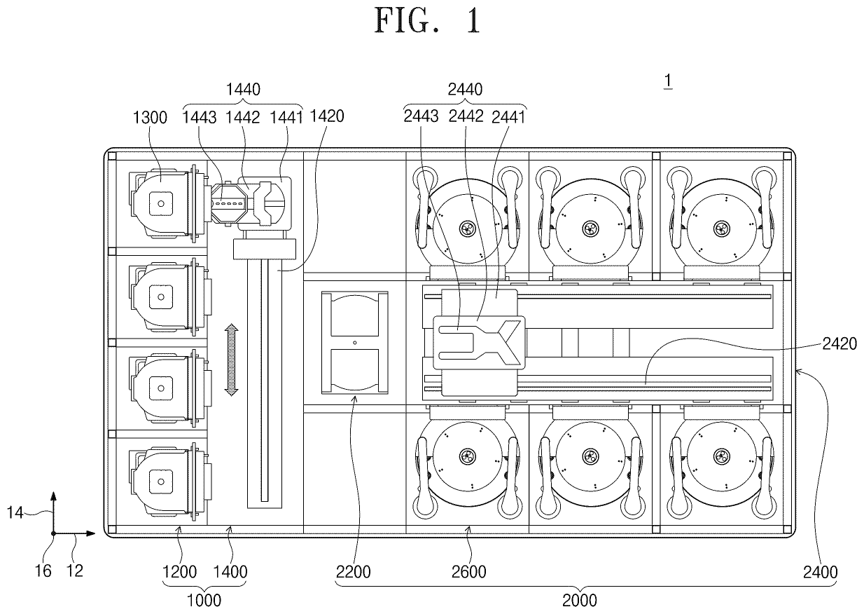

FIG. 1 is a top plan view schematically illustrating a substrate processing facility 1 of the present invention.

Referring to FIG. 1, a substrate processing facility 1 an index module 1000 and a process processing module 2000. The index module 1000 includes a load port 1200 and a transfer frame 1400. The load port 1200, the transfer frame 1400, and the process processing module 2000 are sequentially arranged in a line. Hereinafter, a direction in which the load port 1200, the transfer frame 1400, and the process processing module 2000 are arranged will be referred to as a first direction 12. When viewed from above, a direction perpendicular to the first direction 12 is defined as a second direction 14, and a direction perpendicular to a plane including the first direction 12 and the second direction 14 is defined as a third direction 16.

A carrier 1300 in which the substrate W is accommodated is seated on the load port 1200. A plurality of load ports 1200 is provided, and they are arranged in a line along the second direction 14. In FIG. 1, it is illustrated that four load ports 1200 are provided. The number of load ports 1200 may increase or decrease according to the process efficiency and footprint conditions of the process processing module 2000. A slot (not illustrated) provided to support an edge of the substrate W is formed in the carrier 1300. A plurality of slots is provided in the third direction 16. The substrate W is located in the carrier 1300 to be stacked in a state of being spaced apart from each other along the third direction 16. As the carrier 1300, a Front Opening Unified Pod (FOUP) may be used.

The process processing module 2000 includes a buffer unit 2200, a transfer chamber 2400, and a process chamber 2600. A longitudinal direction of the transfer chamber 2400 is disposed parallel to the first direction 12. The process chambers 2600 are disposed on one side and the other side of the transfer chamber 2400 along the second direction 14, respectively. The process chambers 2600 located on one side of the transfer chamber 2400 and the process chambers 2600 located on the other side of the transfer chamber 2400 are provided to be symmetrical to each other with respect to the transfer chamber 2400. A part of the process chambers 2600 is disposed along a longitudinal direction of the transfer chamber 2400. Also, a part of the process chambers 2600 is disposed to be stacked on each other. That is, the process chambers 2600 may be disposed on one side of the transfer chamber 2400 in an array of A×B (where A and B are each a natural number equal to or greater than 1). Herein, A is the number of process chambers 2600 provided in a row along the first direction 12, and B is the number of process chambers 2600 provided in a row along the third direction 16. When four or six process chambers 2600 are provided on one side of the transfer chamber 2400, the process chambers 2600 are disposed in a 2×2 or 3×2 arrangement. The number of process chambers 2600 may increase or decrease. Unlike the above description, the process chamber 2600 may be provided only to one side of the transfer chamber 2400. Also, unlike the above description, the process chamber 2600 may be provided as a single layer on one side and opposite sides of the transfer chamber 2400.

The buffer unit 2200 is disposed between the transfer frame 1400 and the transfer chamber 2400. The buffer unit 2200 provides a space in which the substrate W stays before the substrate W is transferred between the transfer chamber 2400 and the transfer frame 1400. The buffer unit 2200 is provided with a slot (not illustrated) in which the substrate W is placed, and a plurality of slots (not illustrated) is provided to be spaced apart from each other along the third direction 16. In the buffer unit 2200, a face facing the transfer frame 1400 and a face facing the transfer chamber 2400 are opened.

The transfer frame 1400 transfers the substrate W between the carrier 1300 seated on the load port 1200 and the buffer unit 2200. An index rail 1420 and an index robot 1440 are provided in the transfer frame 1400. The index rail 1420 is provided with a longitudinal direction parallel to the second direction 14. The index robot 1440 is installed on the index rail 1420 and moves linearly in the second direction 14 along the index rail 1420. The index robot 1440 has a base 1441, a body 1442, and an index arm 1443. The base 1441 is installed to be movable along the index rail 1420. The body 1442 is coupled to the base 1441. The body 1442 is provided on the base 1441 to be movable along the third direction 16. Furthermore, the body 1442 is provided to be rotatable on the base 1441. The index arm 1443 is coupled to the body 1442 and is provided to be movable forward and backward with respect to the body 1442. A plurality of index arms 1443 is provided to be individually driven. The index arms 1443 are disposed to be stacked while being spaced apart from each other along the third direction 16. Some of the index arms 1443 may be used to transfer the substrate W from the process processing module 2000 to the carrier 1300, and another may be used to transfer the substrate W from the carrier 1300 to the process processing module 2000. This may prevent particles generated from the substrate W before the process processing from adhering to the substrate W after the process processing in the process of loading and unloading the substrate W by the index robot 140.

The transfer chamber 2400 transfers the substrate W between the buffer unit 2200 and the process chamber 2600 and between the process chambers 2600. A guide rail 2420 and a main robot 2440 are provided in the transfer chamber 2400. The guide rail 2420 is disposed such that the longitudinal direction thereof is parallel to the first direction 12. The main robot 2440 is installed on the guide rail 2420, and moves linearly along the first direction 12 on the guide rail 2420. The main robot 2440 includes a base 2441, a body 2442, and a main arm 2443. The base 2441 is installed to be movable along the guide rail 2420. The body 2442 is coupled to the base 2441. The body 2442 is provided on the base 2441 to be movable along the third direction 16. Furthermore, the body 2442 is provided to be rotatable on the base 2441. The main arm 2443 is coupled to the body 2442 and is provided to be movable forward and backward with respect to the body 2442. A plurality of main arms 2443 is provided to be individually driven. The main arms 2443 are disposed to be stacked while being spaced apart from each other along the third direction 16. The main arm 2443 used to transfer the substrate W from the buffer unit 2200 to the process chamber 2600 and the main arm 2443 used to transfer the substrate W from the process chamber 2600 to the buffer unit 2200 may be different from each other.

A substrate processing apparatus 10 for performing a cleaning process on the substrate W is provided in the process chamber 2600. The substrate processing apparatus 10 provided in each process chamber 2600 may have a different structure depending on the type of cleaning process performed. Selectively, the substrate processing apparatus 10 in each process chamber 2600 may have the same structure. Selectively, the process chambers 2600 are divided into a plurality of groups, and the substrate processing apparatuses 10 provided to the process chambers 2600 belonging to the same group may have the same structure, and the substrate processing apparatuses 10 provided to the process chambers 2600 belonging to different groups may have different structures. For example, when the process chambers 2600 is divided into two groups, the process chambers 2600 of the first group may be provided at one side of the transfer chamber 2400, and the process chambers 2600 of the second group may be provided at the other side of the transfer chamber 2400. Selectively, on one side and the other side of the transfer chamber 2400, the process chambers 2600 of the first group may be provided at lower layers, respectively, and the process chambers 2600 of the second group may be provided at upper layers, respectively. The process chambers 2600 of the first group and the process chambers 2600 of the second group may be classified according to the type of chemical used or the type of cleaning method.

In the following exemplary embodiment, the present invention will be described based on an apparatus for cleaning a substrate W using treatment fluids, such as high-temperature sulfuric acid, alkaline chemical, acidic chemical, rinse liquid, and dry gas as an example. However, the technical idea of the present invention is not limited thereto, and may be applied to all various types of apparatuses performing a process while rotating the substrate W, such as an etching process.

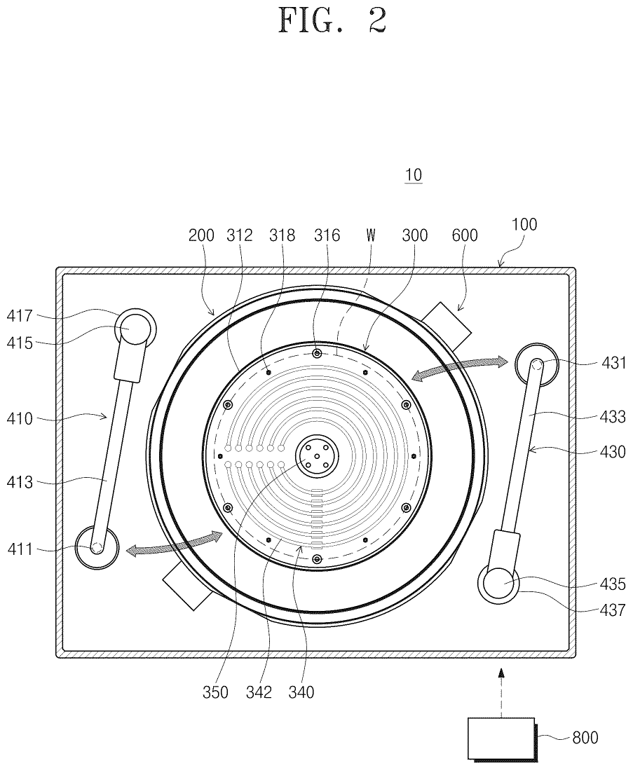

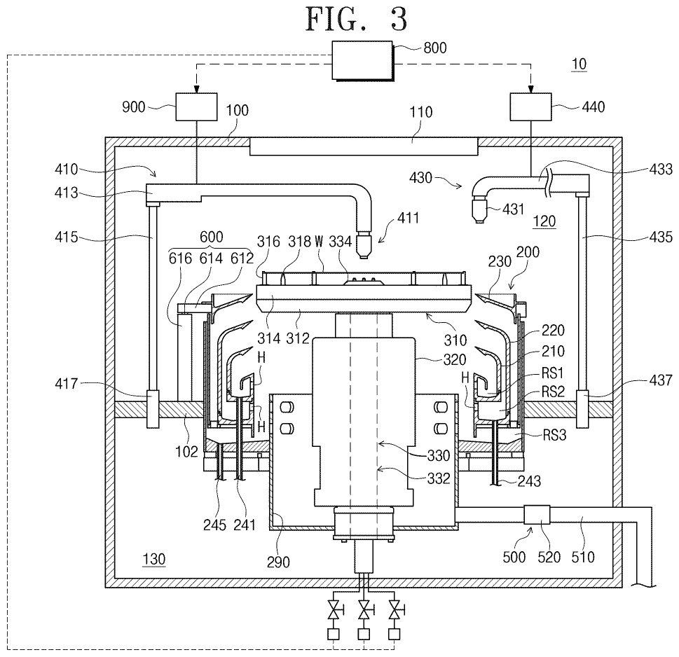

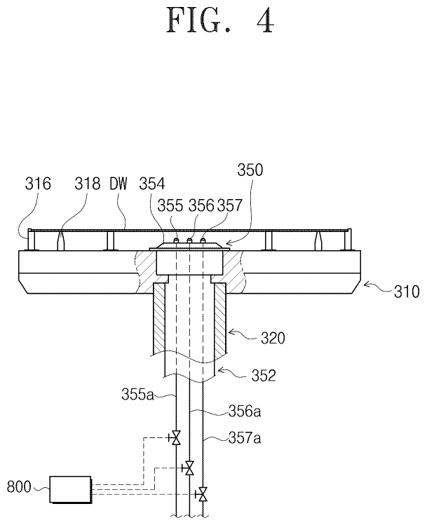

FIG. 2 is a top plan view of the substrate processing apparatus of FIG. 1, FIG. 3 is a cross-sectional view of the substrate processing apparatus of FIG. 1, and FIG. 4 is a diagram for describing a back nozzle unit.

Referring to FIGS. 2 to 4, the substrate processing apparatus 10 includes a chamber 100, a bowl 200, a support unit 300, a chemical nozzle unit 410, a rinse liquid nozzle unit 430, an exhaust unit 500, a lifting unit 600, and a controller 800.

The chamber 100 provides a sealed inner space. An airflow supply member 110 is installed at an upper portion. The airflow supply member 110 forms descending airflow inside the chamber 100.

The airflow supply member 110 filters the high-humidity outdoor air and supplies the filtered outdoor air to the inside of the chamber 100. The high-humidity outdoor air passes through the airflow supply member 110 and is supplied to the inside of the chamber 100 and forms descending airflow. The descending airflow provides uniform airflow to the upper portion of the substrate W, and discharges contaminants generated in a process of processing the surface of the substrate W by the treatment fluid to the exhaust unit 500 together with air through the recovery vessels 210, 220, and 230 of the bowl 200.

The chamber 100 is divided into a process region 120 and a maintenance region 130 by a horizontal partition wall 102. The bowl 200 and the support unit 300 are located in the process region 120. In the maintenance region 130, in addition to the recovery lines 241, 243, and 245 connected to the bowl 200, and the exhaust line 510, a driving unit of the lifting unit 600, a driving unit connected to the chemical nozzle unit 410, a supply line, and the like are located. The maintenance region 130 is isolated from the process region 120.

The bowl 200 has a cylindrical shape with an open top, and has a processing space for processing the substrate W. The open upper surface of the bowl 200 is provided as a loading and unloading passage for the substrate W. The support unit 300 is located in the processing space. The support unit 300 rotates the substrate W while supporting the substrate W during the process.

The bowl 200 provides a lower space in which an exhaust duct 290 is connected to a lower end thereof so that forced exhaust is performed. The bowl 200 is provided with the first to third recovery containers 210, 220, and 230 for introducing and intaking the treatment liquid and gas scattered on the rotating substrate W in multiple stages.

The annular first to third recovery containers 210, 220, and 230 have exhaust ports H that communicate with one common annular space. Specifically, each of the first to third recovery containers 210, 220, and 230 includes a bottom surface having an annular ring shape and a sidewall extending from the bottom surface and having a cylindrical shape. The second recovery container 220 surrounds the first recovery container 210 and is spaced apart from the first recovery container 210. The third recovery container 230 surrounds the second recovery container 220 and is spaced apart from the second recovery container 220.

The first to third recovery containers 210, 220, and 230 provide first to third recovery spaces RS1, RS2, and RS3 into which airflow including a treatment liquid and fumes scattered from the substrate W is introduced. The first recovery space RS1 is defined by the first recovery container 110, the second recovery space RS2 is defined by a spaced space between the first recovery container 110 and the second recovery container 120, and the third recovery space RS3 is defined by a spaced space between the second recovery container 120 and the third recovery container 130.

A central portion of the upper surface of each of the first to third recovery containers 210, 220, and 230 is opened. The first to third recovery containers 210, 220, and 230 are formed as inclined surfaces in which the distance to the corresponding bottom surface gradually increases from the connected sidewall toward the open portion. The treatment liquid scattered from the substrate W flows into the recovery spaces RS1, RS2, and RS3 along the upper surfaces of the first to third recovery containers 210, 220, and 230.

The first treatment liquid introduced into the first recovery space RS1 is discharged to the outside through the first recovery line 241. The second treatment liquid introduced into the second recovery space RS2 is discharged to the outside through the second recovery line 243. The third treatment liquid introduced into the third recovery space RS3 is discharged to the outside through the third recovery line 245.

The support unit 300 may support the substrate W during the process, and may rotate the substrate W during the process.

The support unit 300 may include a spin head 310, a spin driving unit 320, a back nozzle unit 350, and a heating member 340.

The spin head 310 includes a chuck stage 312 and a quartz window 314. The chuck stage 312 has a circular upper surface. The chuck stage 312 is coupled to the spin driving unit 320 and rotated. Chucking pins 316 are installed at the edge of the chuck stage 312. The chucking pins 316 are provided to penetrate the quartz window 314 and protrude upward from the quartz window 314. The chucking pins 316 align the substrate W such that the substrate W supported by a plurality of support pins 318 is placed in a correct position. During the process, the chucking pins 316 come into contact with the side portion of the substrate W to prevent the substrate W from being separated from the correct position.

The quartz window 314 is located above the substrate W and the chuck stage 210. The quartz window 314 is provided to protect the heating member 340. The quartz window 314 may be transparently provided. The quartz window 314 may be rotated together with the chuck stage 312. The quartz window 314 includes support pins 318. The support pins 318 are disposed on the edge of the upper surface of the quartz window 314 to be spaced apart from each other by a predetermined gap. The support pin 318 is provided to protrude upward from the quartz window 314. The support pins 318 support the lower surface of the substrate W so that the substrate W is supported in a state spaced apart from the quartz window 314 in the upward direction.

The spin driving unit 320 has a hollow shape and is coupled to the chuck stage 312 to rotate the chuck stage 312. When the chuck stage 312 is rotated, the quartz window 314 may be rotated together with the chuck stage 312. Also, the components provided in the spin chuck 310 may be positioned independently from the rotation of the spin chuck 310. For example, the heating member 340 to be described later may be positioned independently from the rotation of the spin chuck 310.

The back nozzle unit 350 is provided to inject the treatment fluid to the bottom surface of the substrate W or the dummy substrate when the substrate is processed and when the bowl is cleaned. The back nozzle unit 350 may include a nozzle support shaft 352 and a back nozzle head portion 354.

A back nozzle head portion 354 is located at a center upper portion of the spin head. The back nozzle head portion 354 may include a first back nozzle 355 for discharging a chemical, a second back nozzle 356 for discharging a rinse liquid DIW, and a third back nozzle 357 for discharging dry gas. The third back nozzle 357 injects dry gas to the bottom surface of the substrate. The dry gas dries the rinse liquid remaining on the bottom surface of the substrate after injecting the rinse liquid. The dry gas may be nitrogen gas (N₂).

The nozzle support shaft 352 is inserted into the hollow spin driving unit 320. The nozzle support shaft 352 is provided to be separated from the spin driving unit 320, and the nozzle support shaft 352 is configured not to rotate when the spin driving unit 320 rotates.

A first supply line 355a connected to the first back nozzle 355, a second supply line 356a connected to the second back nozzle 356, and a third supply line 357a connected to the third back nozzle 357 may be provided in the nozzle support shaft 352. The first back nozzle may supply the heated chemical to the substrate W. The chemical may be a high-temperature chemical (for example, SC1) for etching (or cleaning) the surface of the substrate W or a high-temperature liquid for increasing the temperature of the substrate. A valve is installed in each supply line, and the valve may be controlled by the controller 800.

The heating member 340 may heat the substrate W during the process. The heating member 340 is disposed in the spin chuck 310. The heating member 340 may include a lamp 342.

The heating member 340 is installed above the chuck stage 312. The heating member 340 may be provided in a ring shape. A plurality of heating members 340 may be provided. The heating member 340 may have different diameters. The temperatures of the respective heating members 340 may be individually controlled. The heating member 340 may be a lamp 342 that emits light. The lamp 342 may be a lamp 342 that emits light having a wavelength in the infrared region. The lamp 342 may be an infrared lamp 342 (IR lamp). The lamp 342 may heat the substrate W by emitting infrared rays.

The heating member 340 may be subdivided into a plurality of concentric zones. Lamps 342 capable of individually heating each zone may be provided in each zone. The lamps 342 may be provided in a ring shape concentrically arranged at different radial distances from the center of the chuck stage 312. In this case, the number of lamps 342 may be added or decreased depending on the desired degree of temperature control. By controlling the temperature of each individual zone, the heating member 340 may continuously increase or decrease the temperature according to the radius of the substrate W during the process.

The support unit 300 may further include a cooling member (not illustrated), a heat insulating plate (not illustrated), and a heat dissipation plate (not illustrated). The cooling member may be disposed in the spin chuck 310 to supply a cooling fluid into the spin chuck 310. For example, the cooling member may supply a cooling fluid to a flow path formed in the heat dissipation plate.

The heat insulating plate may be disposed within the spin chuck 310. Also, the heat dissipation plate may be disposed under the heating member 340 within the spin chuck 310. The heat insulating plate may be provided of a transparent material. The heat insulating plate may be made of a transparent material so that light emitted by the heating member 340 may pass through the heat insulating plate. In addition, the heat insulating plate may be made of a material having low thermal conductivity. For example, the heat insulating plate may be made of a material having lower thermal conductivity than the heat dissipation plate. For example, the heat insulating plate may be made of a material including glass. The heat insulating plate may be made of a material including Neoceram. The heat insulating plate may be made of a material including glass ceramic. However, the present invention is not limited thereto, and the heat insulating plate may be made of a material including ceramic.

A reflection plate may be disposed within the spin chuck 310. In addition, the reflection plate may be disposed under the heat insulating plate in the spin chuck 310. The reflection plate may be made of a material that reflects light emitted by the heating member 340. The reflection plate may be made of a material that reflects light having a wavelength in an infrared region. The reflection plate may be made of a material containing metal. The reflection plate may be made of a material containing aluminum. The reflection plate may be made of a material containing silver-plated aluminum whose surface is plated with silver (Ag).

The heat dissipation plate may discharge heat transferred from the heat insulating plate to the outside. In addition, a flow path through which a cooling fluid supplied by the cooling member flows may be formed in the heat dissipation plate. The heat dissipation plate may be disposed within the spin chuck 310. In addition, the heat dissipation plate may be disposed under the reflection plate in the spin chuck. The heat dissipation plate may be made of a material having high thermal conductivity. For example, the heat dissipation plate may be made of a material having higher thermal conductivity than the heat insulating plate described above. The heat dissipation plate may be made of a material containing metal. The heat dissipation plate may be made of a material containing aluminum and/or silver.

The chemical nozzle unit 410 may treat the substrate W by supplying the chemical to the substrate W. The chemical nozzle unit 410 may supply the heated chemical to the substrate W. The chemical may be a high-temperature chemical for etching the surface of the substrate W.

The chemical nozzle unit 410 may include a first nozzle 411, a nozzle arm 413, a support rod 415, and a nozzle driver 417. The first nozzle 411 receives the chemical through the chemical supply unit 900. The first nozzle 411 discharges the chemical to the surface of the substrate W. The nozzle arm 413 is an arm elongated in one direction, and the first nozzle 411 is mounted on a front end thereof. The nozzle arm 413 supports the first nozzle 411. The support rod 415 is mounted on a rear end of the nozzle arm 413. The support rod 415 is disposed below the nozzle arm 413. The support rod 415 is disposed perpendicular to the nozzle arm 413. The nozzle driver 417 is provided on a lower end of the support rod 415. The nozzle driver 417 rotates the support rod 415 about a longitudinal axis of the support rod 415. The nozzle arm 413 and the first nozzle 411 swing about the support rod 415 as an axis by the rotation of the support rod 415. The first nozzle 411 may swing and move between the outer side and the inner side of the bowl 200. And, the first nozzle 411 may swing and move in a section between the center and the edge region to discharge the chemical.

The rinse liquid nozzle unit 430 may include a second nozzle 431, a nozzle arm 433, a support rod 435, and a nozzle driver 437. The second nozzle 431 receives the rinse liquid through the rinse liquid supply unit 440. The second nozzle 431 discharges the rinse liquid DIW to the surface of the substrate W. The nozzle arm 433 is an arm elongated in one direction, and the second nozzle 431 is mounted on the front end thereof. The nozzle arm 433 supports the second nozzle 431. A support rod 433 is mounted on a rear end of the nozzle arm 435. The support rod 435 is disposed on a lower portion of the nozzle arm 433. The support rod 435 is disposed to be perpendicular to the nozzle arm 433. The nozzle driver 437 is provided on a lower end of the support rod 435. The nozzle driver 437 rotates the support rod 435 about a longitudinal axis of the support rod 435. The nozzle arm 435 and the second nozzle 431 swing and move about the support rod 435 as an axis by the rotation of the support rod 435. The second nozzle 431 may swing and move between the outer side and the inner side of the bowl 200.

The exhaust unit 500 may exhaust the inside of the bowl 100. For example, the exhaust unit 500 is provided to provide an exhaust pressure (intake pressure) to a recovery container that recovers a treatment liquid from among the first to third recovery containers 210, 220, and 230 during a process. The exhaust unit 500 includes an exhaust line 510 and a damper 520 which are connected to the exhaust duct 290. The exhaust line 510 receives an exhaust pressure from an exhaust pump (not illustrated) and is connected to a main exhaust line buried in the bottom space of the semiconductor production line.

Meanwhile, the bowl 200 is coupled to the lifting unit 600 for changing the vertical position of the bowl 200. The lifting unit 600 linearly moves the bowl 200 in the vertical direction. As the bowl 200 is moved up and down, a relative height of the bowl 200 with respect to the support unit 300 is changed.

The lifting unit 600 includes a bracket 612, a moving shaft 614, and a driver 616. The bracket 612 is fixedly installed on an outer wall of a treating container 100. The moving shaft 614 that moves in the vertical direction by the driver 616 is fixedly coupled to the bracket 612. When the substrate W is loaded or unloaded on the support unit 300, the bowl 200 descends so that the support unit 300 protrudes upward from the bowl 200. Also, during the process, the height of the bowl 200 is adjusted so that the treatment liquid may be introduced into the preset recovery containers 210, 220, and 230 according to the type of treatment liquid supplied to the substrate W. The bowl 200 may have different types of the treatment liquid and the contamination gas recovered for each of the recovery spaces RS1, RS2, and RS3.

The controller 800 may control the chemical nozzle unit 410 and the rinse liquid nozzle unit 430 so that the chemical 410 supplies the chemical to the substrate first and then supplies the rinse liquid to the substrate in the substrate processing operation. The controller 800 may control the rinse liquid nozzle unit 430 and the back nozzle unit 350 to clean the bowl 200 and stabilize the temperature of the chemical in the bowl cleaning operation.

The controller 800 may control the spin head 310 at a first rotation speed and a second rotation speed in the bowl cleaning operation. The second rotation speed may be higher than the first rotation speed. That is, the controller 800 may control the support unit 300 so that the rotation speed of the discharge of the dry gas is faster than the rotation speed of the discharge of the rinse liquid in the bowl cleaning operation.

The controller 800 may control the substrate processing apparatus. The controller 800 may control the components of the process chamber so that the substrate is processed according to a setting process as described above. The controller 800 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

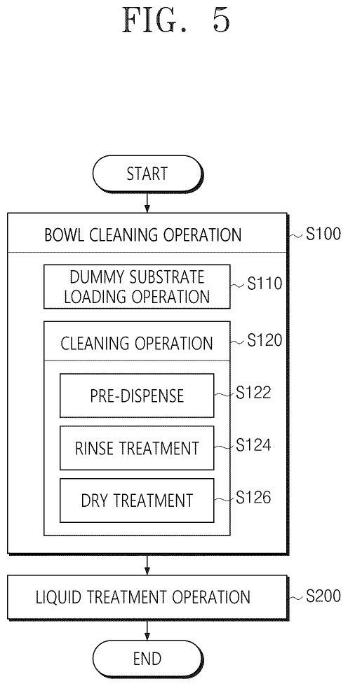

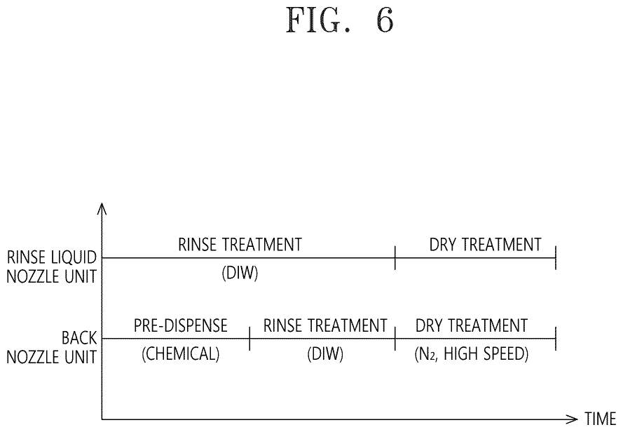

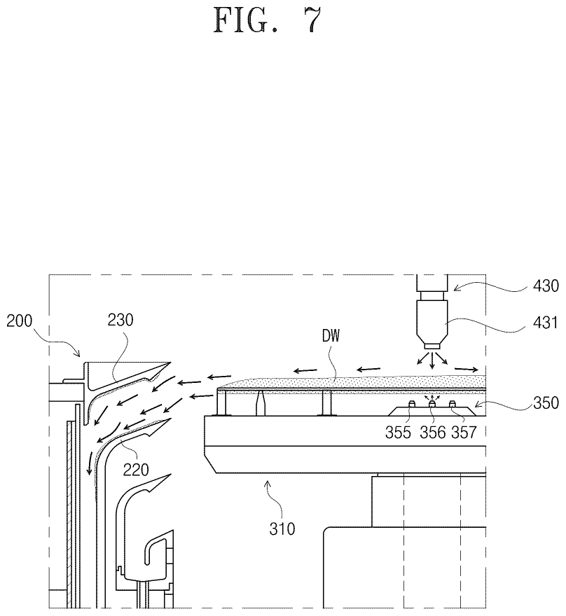

FIG. 5 is a flowchart of a substrate processing method according to an exemplary embodiment of the present invention, FIG. 6 is a table illustrating a supply time point of a chemical, a rinse liquid, and dry gas in the bowl cleaning operation, and FIG. 7 is a diagram illustrating a process of scattering a rinse liquid in the bowl cleaning.

Referring to FIG. 5, the substrate processing method may include a bowl cleaning operation S100 and a liquid treating operation S200.

The bowl cleaning operation S100 includes cleaning the bowl 200 surrounding the spin head 310 before the liquid treatment operation S200 and simultaneously performing temperature stabilization of the treatment fluid discharged from the back nozzle unit 350 of the spin head 310.

In the liquid treatment operation S200, the substrate is treated by supplying the treatment fluid to the substrate W supported by the spin head 310. The liquid treatment operation S200 may include a chemical treatment, a rinse treatment, and a dry treatment. In the liquid treatment operation S200, the treatment fluid is discharged through the chemical nozzle unit 410, the rinse liquid nozzle unit 430, and the back nozzle unit 350.

The liquid treatment operation S200 may be performed in a state in which the substrate is supported by the support pins 318 and the chucking pins 316 to be positioned at an upper portion of the spin head 310. To briefly describe the liquid treatment operation, the first nozzle 411 of the liquid chemical unit 410 and the first back nozzle 355 of the back nozzle unit 350 perform a predetermined chemical treatment by discharging the chemical to the upper surface and the bottom surface of the rotating substrate W, respectively. The chemical flows along the upper surface and the lower surface of the substrate W by the centrifugal force caused by the rotation of the substrate W, and is then scattered laterally from the end edge of the substrate W. Accordingly, the chemical treatment of the substrate W proceeds. The chemical scattered from the end edge of the rotating substrate W is recovered through the recovery cup of the bowl 200. In the rinse treatment, the substrate is rinsing-treated by supplying the rinse liquid to the substrate that is rotated together with the spin head 310. The rinse liquid is discharged from the second nozzle 431 of the rinse liquid nozzle unit 430 and the second back nozzle 356 of the back nozzle unit 350. After that, the substrate W is rotated at high speed and shook off to perform a dry treatment.

The bowl cleaning operation S100 is performed before the liquid treatment operation S200. The bowl cleaning operation S100 may include a loading operation S110 of loading a dummy substrate DW onto the spin head 310 and a cleaning operation S120.

In the cleaning operation S120, the rinse liquid nozzle unit 430 discharges the rinse liquid to the upper surface of the dummy substrate DW rotated by the spin head 310, and the back nozzle unit 350 sequentially discharges the cleaning fluid (chemical, rinse liquid, and dry gas) to the bottom surface of the dummy substrate DW.

In the cleaning operation S120, the rinse liquid nozzle unit 430 and the back nozzle unit 350 are used. The cleaning operation S120 may include a pre-dispense operation S122, a rinse treatment operation S124, and a dry treatment operation S126. For reference, the rinse liquid nozzle unit 430 discharges the rinse liquid to the upper surface of the dummy substrate DW during the pre-dispense operation S122 and the rinse treatment operation S124. Hereinafter, the operation in the back nozzle unit 350 will be described in detail.

In the pre-dispense operation S122, the first back nozzle 355 discharges the chemical to the bottom surface of the dummy substrate DW. In the pre-dispense operation S122, a discharge amount and discharge time may be set to be different according to a type of chemical and a set temperature of the chemical. The pre-dispense operation S122 is an operation of stabilizing the temperature of the chemical discharged from the first back nozzle 355. For example, in the pre-dispense operation S122, a discharge amount and discharge time of the chemical may increase as the set temperature of the chemical discharged from the first back nozzle 355 increases. For example, when the set temperature of the chemical is 80 degrees, the first back nozzle 355 may discharge the chemical for 6 minutes based on 1600 cc, and when the set temperature of the chemical is 50 degrees, the first back nozzle 355 may discharge the chemical for 90 seconds based on 950 cc.

In the rinsing processing operation S124, the second back nozzle 356 discharges the rinse liquid DIW to the bottom surface of the dummy substrate DW. The rinse liquid discharged to the upper surface of the dummy substrate DW is scattered from the upper surface of the dummy substrate DW to clean the bowl, and the rinse liquid discharged to the bottom surface of the dummy substrate DW is scattered from the bottom surface of the dummy substrate DW to clean the bowl. In other words, since the scattering range of the rinse liquid scattered from the upper surface of the dummy substrate DW and the scattering range of the rinse liquid scattered from the bottom surface of the dummy substrate DW are different, the rinse liquid may be scattered over a wider range to clean the bowl 210.

In the dry treatment operation S126, after the rinse treatment operation S124, the third back nozzle 357 discharges the drying gas to the bottom surface of the dummy substrate DW to drying-treat the dummy substrate DW and the bowl 210.

In the pre-dispense operation S122 and the rinse treatment operation S124, the dummy substrate DW is rotated at a first rotation speed, and in the dry treatment operation S126, the dummy substrate DW is rotated at a second speed faster than the first rotation speed.

Meanwhile, the rinse liquid discharged to the upper surface of the dummy substrate DW is stopped before the dry gas is discharged to the bottom surface of the dummy substrate DW.

The substrate processing method with the above-described configuration may remove stagnant particles of the chemical used in the subsequent liquid treating process of the substrate and stabilize the temperature of the chemical by simultaneously free-discharging the chemical stagnated in the first supply line 355a of the back nozzle unit 350 in the process of cleaning the bowl 210 before the liquid treatment of the substrate.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A substrate processing method comprising:
a liquid treatment operation of processing a substrate by supplying a treatment liquid to the substrate supported on a spin head; and
a bowl cleaning operation of cleaning a bowl surrounding the spin head and simultaneously stabilizing a temperature of a treatment fluid discharged from a back nozzle of the spin head before the liquid treatment operation.

2. The substrate processing method of claim 1, wherein the bowl cleaning operation includes:
a loading operation of loading a dummy substrate onto the spin head; and
a cleaning operation in which an upper nozzle member discharges a cleaning fluid to an upper surface of the dummy substrate rotated by the spin head and the back nozzle discharges the cleaning fluid to a bottom surface of the dummy substrate.

3. The substrate processing method of claim 2, wherein the cleaning operation includes:
a pre-dispense operation in which the back nozzle discharges a chemical to the bottom surface of the dummy substrate; and
a rinse treatment operation in which the back nozzle discharges a rinse liquid to the bottom surface of the dummy substrate.

4. The substrate processing method of claim 3, wherein the cleaning operation further includes a dry treatment operation in which the back nozzle discharges dry gas to the bottom surface of the dummy substrate after the rinse treatment operation.

5. The substrate processing method of claim 3, wherein in the pre-dispense operation, a discharge amount and discharge time are set differently according to the type of chemical and a set temperature of the chemical.

6. The substrate processing method of claim 3, wherein the pre-dispense operation is performed for a period of time during which the temperature of the chemical discharged from the back nozzle is stabilized.

7. The substrate processing method of claim 3, wherein in the pre-dispense operation, a discharge amount and discharge time of the chemical increase as a set temperature of the chemical discharged from the back nozzle increases.

8. The substrate processing method of claim 3, wherein in the liquid treatment operation, the chemical of which the temperature is stabilized in the bow cleaning operation is supplied to the bottom surface of the substrate.

9. The substrate processing method of claim 4, wherein in the pre-dispense operation and the rinse treatment operation, the dummy substrate is rotated at a first rotation speed, and
in the dry treatment operation, the dummy substrate is rotated at a second rotation speed.

10. The substrate processing method of claim 9, wherein the second rotation speed is higher than the first rotation speed.

11. The substrate processing method of claim 2, wherein in the cleaning operation,
the rinse liquid is discharged to the upper surface of the dummy substrate, and
a chemical, a rinse liquid, and dry gas are sequentially discharged to the bottom surface of the dummy substrate, and
the rinse liquid discharged to the upper surface of the dummy substrate is stopped before the dry gas is discharged to the bottom surface of the dummy substrate.

12.-18. (canceled)

19. A substrate processing method in a substrate processing apparatus including a spin head that rotatably supports a substrate and has a back nozzle for discharging a chemical to a bottom surface of the substrate, an upper nozzle member that discharges a rinse liquid to an upper surface of the substrate, and a bowl disposed in a circumference of the spin head, the substrate processing method comprising:
a liquid treatment operation in which the upper nozzle member and the back nozzle discharge a chemical to an upper surface and a lower surface of the substrate supported by the spin head to process the substrate; and
a bowl cleaning operation of cleaning a bowl surrounding the spin head and simultaneously stabilizing a temperature of the chemical discharged from the back nozzle before the liquid treatment operation,
wherein the bowl cleaning operation includes:
a loading operation of loading a dummy substrate onto the spin head; and
a cleaning operation in which the upper nozzle member discharges a rinse liquid to an upper surface of the dummy substrate rotated by the spin head, and the back nozzle discharges the chemical, rinse liquid, and dry gas to a bottom surface of the dummy substrate,
the cleaning operation includes:
a pre-dispense operation in which the back nozzle discharges the chemical to the bottom surface of the dummy substrate for a period of time during which a temperature of the chemical discharged from the back nozzle is stabilized;
a rinse treatment operation in which the back nozzle discharges the rinse liquid to the bottom surface of the dummy substrate; and
a dry treatment operation in which the back nozzle discharges dry gas to the bottom surface of the dummy substrate after the rinse treatment operation, and
in the pre-dispense operation, a discharge amount and discharge time are set differently according to the type of chemical and a set temperature of the chemical.

20. The substrate processing method of claim 19, wherein the discharge amount and the discharge time of the chemical in the pre-dispense operation increase as a set temperature of the chemical discharged from the back nozzle increases,
in the liquid treatment operation, the chemical temperature-stabilized in the bowl cleaning operation is supplied to the bottom surface of the substrate,
in the pre-dispense operation and the rinse treatment operation, the dummy substrate is rotated at a first rotation speed, and
in the dry treatment operation, the dummy substrate is rotated at a second rotation speed higher than the first rotation speed.
